(19) United States
(12) Patent Application Publication
(10) Pub. No.: US 2023/0258886 A1
(43) Pub. Date: Aug. 17, 2023

(54) SEMICONDUCTOR PACKAGE STRUCTURE WITH MULTIPLE WAVEGUIDES

(71) Applicant: Taiwan Semiconductor Manufacturing Company, Ltd., Hsinchu (TW)

(72) Inventors: Wen-Shiang Liao, Miaoli County (TW); Hsien-Wei Chen, Hsinchu City (TW)

(73) Assignee: Taiwan Semiconductor Manufacturing Company, Ltd., Hsinchu (TW)

(21) Appl. No.: 17/673,728

(22) Filed: Feb. 16, 2022

(51) Int. Cl. G02B 6/42; H01L 25/16; H01L 23/538; H01L 23/31; H01L 23/00

(52) U.S. Cl. CPC G02B 6/4246; H01L 25/167; H01L 23/5383; H01L 23/3121; H01L 24/73; G02B 6/4253; H01L 2224/73204

(57) ABSTRACT

A package structure including a wiring substrate, an interposer and a semiconductor die is provided. The interposer is disposed on and electrically connected to the wiring substrate, and the interposer includes an embedded dielectric waveguide. The semiconductor die is disposed on and electrically connected to the interposer. In some embodiments, the interposer includes a semiconductor substrate; dielectric layers stacked on the semiconductor substrate; and conductive wirings disposed on and electrically connected to the semiconductor substrate, wherein the conductive wirings and the embedded dielectric waveguide are embedded in the dielectric layers.

### BACKGROUND

Integrated optical waveguides are often used as components in integrated optical circuits having multiple photonic functions. Integrated optical waveguides are used to confine and guide light from a first point on an integrated chip (IC) to a second point on the IC with minimal attenuation. Generally, integrated optical waveguides provide functionality for signals imposed on optical wavelengths in the visible spectrum.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram illustrating an exemplary semiconductor structure in accordance with some embodiments of the present disclosure.

FIG. 1B schematically illustrates a 3D view of the semiconductor structure shown in FIG. 1A in accordance with some embodiments of the present disclosure.

FIG. 1C schematically illustrates a 3D view of the semiconductor structure shown in FIG. 1A in accordance with some other embodiments of the present disclosure.

FIG. 2 is a schematic diagram illustrating an exemplary semiconductor structure in accordance with some embodiments of the present disclosure.

FIGS. 3 through 15 schematically illustrates a process flow for fabricating an interposer.

FIGS. 16 through 24 schematically illustrates a process flow for fabricating a package structure including the interposer shown in FIG. 15.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Package and the method of forming the same are provided in accordance with various exemplary embodiments. The intermediate stages of forming the package are illustrated. The variations of the embodiments are discussed. Throughout the various views and illustrative embodiments, like reference numbers are used to designate like elements.

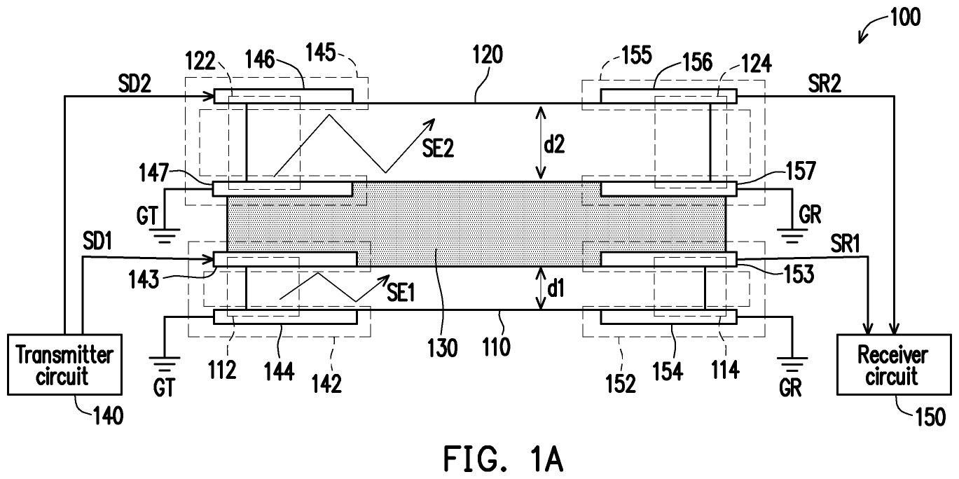

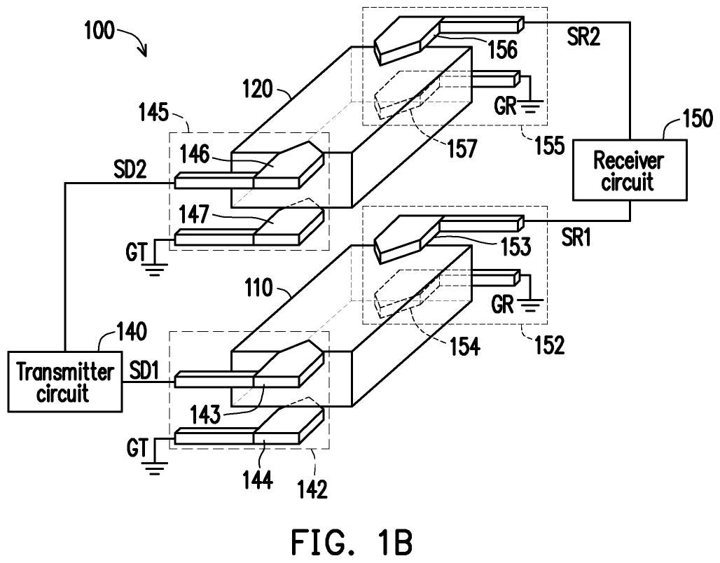

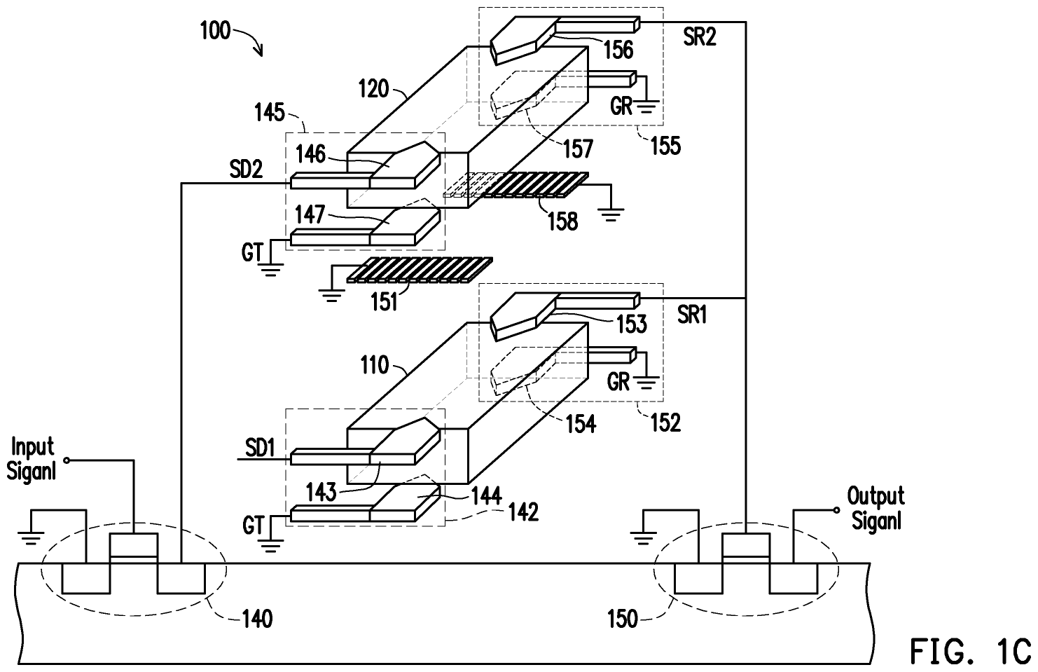

FIG. 1A is a schematic diagram illustrating an exemplary semiconductor structure 100 according to an embodiment of the present disclosure. Referring to FIG. 1A, the semiconductor structure 100 includes a first dielectric waveguide 110, a second dielectric waveguide 120, an inter-level dielectric (ILD) layer 130, a transmitter circuit 140, a first transmitter coupling structure 142, a second transmitter coupling structure 145, a receiver circuit 150, a first receiver coupling structure 152 and a second receiver coupling structure 155. The first dielectric waveguide 110 and the second dielectric waveguide 120 are disposed one over the other, and the first dielectric waveguide 110 and the second dielectric waveguide 120 are configured to propagate signals. In some embodiments, the first dielectric waveguide 110 is configured to guide an electromagnetic signal SE1 from a transmission end portion 112 to a receiver end portion 114 of the first dielectric waveguide 110. The second dielectric waveguide 120 is configured to guide an electromagnetic signal SE2 from a transmission end portion 122 to a receiver end portion 124 of the second dielectric waveguide 120. In some embodiments, at least one of the electromagnetic signals SE1 and SE2 respectively propagated by the first dielectric waveguide 110 and the second dielectric waveguide 120 is a single ended signal. In some embodiments, at least one of the electromagnetic signals SE1 and SE2 respectively propagated by the first dielectric waveguide 110 and the second dielectric waveguide 120 is a differential signal.

In some embodiments, the electromagnetic signal SE1 propagated by the first dielectric waveguide 110 is different in frequency from the electromagnetic signal SE2 propagated by the second dielectric waveguide 120. For example, the semiconductor structure 100 is employed in 5G millimeter-wave (mm-wave) transmission. In that case, the first dielectric waveguide 110 located below the second dielectric waveguide 120 can be configured to transmit the electromagnetic signal SE1 having a frequency (e.g., about 5 GHz) lower than that of the electromagnetic signal SE2 (e.g., over 10 GHz). Those skilled in the relevant art will recognize that the first dielectric waveguide 110 located below the second dielectric waveguide 120 can be configured to transmit the electromagnetic signal SE1 having a frequency greater than or equal to that of the electromagnetic signal SE2 in the 5G mm-wave transmission without departing from the spirit and scope of the present disclosure.

By way of example but not limitation, a dielectric constant of the first dielectric waveguide 110 is different from (i.e., greater than or smaller than) a dielectric constant of the second dielectric waveguide 120. In addition, a thickness d1 of the first dielectric waveguide 110 is different from (i.e., greater than or smaller than) a thickness d2 of the second dielectric waveguide 120. As a result, the first dielectric waveguide 110 and the second dielectric waveguide 120 can be configured to propagate the electromagnetic signals SE1 and SE2 at different frequencies.

The ILD layer 130 is disposed between the first dielectric waveguide 110 and the second dielectric waveguide 120, such that the first dielectric waveguide 110 and the second dielectric waveguide 120 are spatially separated from each other. In the embodiment shown in FIG. 1, the second dielectric waveguide 120 is disposed over the ILD layer 130, and the ILD layer 130 is disposed over the first dielectric waveguide 110. In some embodiments, a dielectric constant of the ILD layer 130 is smaller than a dielectric constant of the first dielectric waveguide 110 and a dielectric constant of the second dielectric waveguide 120. In some examples, the ILD layer 130 may include relatively low dielectric constant material(s) such as fluorine-doped silicon dioxide (SiO₂), carbon-doped silicon dioxide, porous silicon dioxide, or a similar material. In some examples, the ILD layer 130 may include polymer layer(s) formed of polyimide (PI), polybenzoxazole (PBO), benzocyclobutene (BCB), epoxy, silicone, acrylates, nano-filled phenol resin, siloxane, a fluorinated polymer, polynorbornene, or the like, but the present disclosure is not limited thereto.

The transmitter circuit 140 is configured to generate a driver signal SD1, carrying first data to be transmitted, and send the driver signal SD1 to the first transmitter coupling structure 142 of the first dielectric waveguide 110. Also, the transmitter circuit 140 is configured to generate a driver signal SD2, carrying second data to be transmitted, and send the same to the second transmitter coupling structure 145 of the second dielectric waveguide 120. The receiver circuit 150 is configured to receive a receiver signal SR1 including the data carried by the driver signal SD1 from the first receiver coupling structure 152 of the first dielectric waveguide 110, and receive a receiver signal SR2 including the data carried by the driver signal SD2 from the second receiver coupling structure 155 of the second dielectric waveguide 120. As a result, the first dielectric waveguide 110 and the second dielectric waveguide 120 can be used as multiple channels for transmitting data provided by the transmitter circuit 140.

The first transmitter coupling structure 142 is configured to couple the driver signal SD1 from the transmitter circuit 140 to the transmission end portion 112, and accordingly produce the electromagnetic signal SE1. In the present embodiment, when the driver signal SD1 is coupled to the transmission end portion 112, an electric field is induced in the transmission end portion 112. The induced electric field causes electromagnetic radiation corresponding to the driver signal SD1 to be coupled into the first dielectric waveguide 110, thereby producing the electromagnetic signal SE1.

The first receiver coupling structure 152, coupled between the receiver end portion 114 and the receiver circuit 150, is configured to couple the electromagnetic signal SE1 to produce the receiver signal SR1 including the first data carried by the driver signal SD1. For example, the first transmitter coupling structure 142 is configured to couple the driver signal SD1 into the first dielectric waveguide 110 from the transmission end portion 112 as electromagnetic radiation, or the electromagnetic signal SE1. The first receiver coupling structure 152 is configured to couple the electromagnetic radiation, or the electromagnetic signal SE1, out of the first dielectric waveguide 110 as the receiver signal SR1.

In the present embodiment, the second transmitter coupling structure 145 is configured to couple the driver signal SD2 from the transmitter circuit 140 to the transmission end portion 122, and accordingly produce the electromagnetic signal SE2. The second receiver coupling structure 155 is coupled between the receiver end portion 124 and the receiver circuit 150, and is configured to couple the electromagnetic signal SE2 to produce the receiver signal SR2 including the data carried by the driver signal SD2. For example, the second transmitter coupling structure 145 is configured to couple the driver signal SD2 into the second dielectric waveguide 120 from the transmission end portion 122 as electromagnetic radiation, or the electromagnetic signal SE2. The second receiver coupling structure 155 is configured to couple the electromagnetic radiation, or the electromagnetic signal SE2, out of the second dielectric waveguide 120 as the receiver signal SR2.

In some embodiments, at least one of the first transmitter coupling structure 142 and the second transmitter coupling structure 145 may include a pair of metal structures. Moreover, at least one of the first receiver coupling structure 152 or the second receiver coupling structure 155 may include a pair of metal structures. Referring to FIG. 1B, which illustrates a 3D view of the semiconductor structure 100 shown in FIG. 1A according to an embodiment of the present disclosure. In the embodiment shown in FIG. 1B, each of the first dielectric waveguide 110 and the second dielectric waveguide 120 has a rectangular cross-section. For example, at least one of the first dielectric waveguide 110 and the second dielectric waveguide 120 can be a dielectric slab waveguide.

The first transmitter coupling structure 142 may include a pair of transmitter electrodes 143 and 144 disposed at opposite surfaces of the transmission end portion 122 of the embedded dielectric waveguide 120. The transmitter electrode 143 includes a metal structure, which may further include microstrips, disposed over the first dielectric waveguide 110. In addition, the metal structure is configured to couple the driver signal SD1 to the first dielectric waveguide 110 at the transmission end portion 112 shown in FIG. 1A. The transmitter electrode 144 includes a metal structure, which may further include microstrips, disposed below the first dielectric waveguide 110. In addition, this metal structure is coupled between the first dielectric waveguide 110 at the transmission end portion 112 shown in FIG. 1A and a transmitter ground GT (e.g., a ground terminal). In some embodiments, the transmitter electrode 143 and the transmitter electrode 144 are located on opposite sides of the first dielectric waveguide 110. In some embodiments, the transmitter electrode 143 and the transmitter electrode 144 are symmetrically disposed with respect to the first dielectric waveguide 110. In some embodiments, the shapes and/or patterns of the transmitter electrode 143 and the transmitter electrode 144 are identical with each other.

The first receiver coupling structure 152 may include a pair of receiver electrodes 153 and 154 disposed at opposite surfaces of the receiver end 114 of the embedded dielectric waveguide 110. The receiver electrode 153 includes a metal structure, which may include microstrips, disposed over the first dielectric waveguide 110. The metal structure is configured to couple the first dielectric waveguide 110, or the receiver end portion 114 shown in FIG. 1A, to the receiver circuit 150. The receiver electrode 154 includes a metal structure, which may include microstrips, disposed below the first dielectric waveguide 110. The metal structure is coupled between the first dielectric waveguide 110 and a receiver ground GR, such as a ground terminal. In the present embodiment, the receiver electrode 153 and the receiver electrode 154 are located on opposite sides of the first dielectric waveguide 110. In some embodiments, the receiver electrode 153 and the receiver electrode 154 are symmetrically disposed with respect to the first dielectric waveguide 110. In some embodiments, the shapes and/or patterns of the receiver electrode 153 and the receiver electrode 154 are identical with each other.

In the present embodiment, the transmitter electrode 143 and the receiver electrode 153 are disposed within a metal layer over the first dielectric waveguide 110. In addition, the transmitter electrode 144 and the receiver electrode 154 are disposed within a metal layer below the first dielectric waveguide 110.

In the embodiment shown in FIG. 1B, the second transmitter coupling structure 145 may include a pair of transmitter electrodes 143 and 144. The transmitter electrode 146 includes a metal structure, which may include microstrips, disposed over the second dielectric waveguide 120. The metal structure is configured to couple the driver signal SD1 to the second dielectric waveguide 120, or the transmission end portion 122 shown in FIG. 1A. The transmitter electrode 147 includes a metal structure, which may include microstrips, disposed below the second dielectric waveguide 120. The metal structure is coupled between the second dielectric waveguide 120 and the transmitter ground GT. In the present embodiment, the transmitter electrode 146 and the transmitter electrode 147 are located on opposite sides of the second dielectric waveguide 120. In some embodiments, the transmitter electrode 146 and the transmitter electrode 147 are symmetrically disposed with respect to the first dielectric waveguide 110. In some embodiments, the shapes and/or patterns of the transmitter electrode 146 and the transmitter electrode 147 are identical with each other.

The second receiver coupling structure 155 may include a pair of receiver electrodes 156 and 157. The receiver electrode 156 includes a metal structure, which may include microstrips, disposed over the second dielectric waveguide 120. The metal structure is configured to couple the second dielectric waveguide 120, or the receiver end portion 124 shown in FIG. 1A, to the receiver circuit 150. The receiver electrode 157 includes a metal structure, which may include microstrips, disposed below the second dielectric waveguide 120. The metal structure is coupled between the second dielectric waveguide 120 and the receiver ground GR. In the present embodiment, the receiver electrode 156 and the receiver electrode 157 are located on opposite sides of the first dielectric waveguide 110. In some embodiments, the receiver electrode 156 and the receiver electrode 157 are symmetrically disposed with respect to the second dielectric waveguide 120. In some embodiments, the shapes and/or patterns of the receiver electrode 156 and the receiver electrode 157 are identical with each other.

In the present embodiment, the transmitter electrode 146 and the receiver electrode 156 are disposed within a metal layer over the second dielectric waveguide 120. In some addition, the transmitter electrode 147 and the receiver electrode 157 are disposed within a metal layer below the second dielectric waveguide 120. The first dielectric waveguide 110, the second dielectric waveguide 120, the transmitter electrode 146, the receiver electrode 156, the transmitter electrode 147 and the receiver electrode 157 may be fabricated in an interposer (e.g., a silicon interposer, an organic interposer, or the like) of a Chip-on-Wafer-on Substrate (CoWoS) type package.

With multiple dielectric waveguide channels, each being coupled between the transmitter circuit 140 and the receiver circuit 150 though a corresponding transmitter coupling structure and a corresponding receiver coupling structure, the semiconductor structure 100 can provide high speed data transmission because of wide bandwidth of electromagnetic radiation that can be transmitted in each dielectric waveguide channel. For example, at least one of the first dielectric waveguide 110 and the second dielectric waveguide 120 can transmit electromagnetic radiation having a bandwidth ten times wider than that of the visible spectrum. As a result, the semiconductor structure 100 is suitable for 5G communication, high performance computing (HPC) applications, artificial intelligence (AI) and neuro-engineering (or neural engineering). In addition, the semiconductor structure 100 can provide different data communication applications when different dielectric waveguide channels are configured to transmit electromagnetic radiation in different frequency bands. In some examples, a waveguide channel having a higher dielectric constant can be used for lower frequency transmission because its thickness and size can be smaller, thus saving manufacturing costs.

Referring to FIG. 1B and FIG. 1C, the semiconductor structure shown in FIG. 1C is similar with the semiconductor structure shown in FIG. 1B except that the semiconductor structure shown in FIG. 1C further includes a first shielding pattern 151 and a second shielding pattern 158, wherein the first shielding pattern 151 is between the first transmitter coupling structure 142 and the second transmitter coupling structure 145, and the second shielding pattern 158 is between the first receiver coupling structure 152 and the second receiver coupling structure 155. In some embodiments, the first shielding pattern 151 and the second shielding pattern 158 are metallic shielding patterns. In some embodiments, the first shielding pattern 151 and the second shielding pattern 158 are electrically grounded. Furthermore, the transmitter circuit 140 and the receiver circuit 150 may include transistors formed in a substrate of an interposer. In some embodiments, the transistors included in the transmitter circuit 140 and the receiver circuit 150 are metal-oxide-semiconductor field effect transistors (MOSFETs). As illustrated in FIG. 1C, the transmitter electrodes 143 and 146 are electrically connected to a drain terminal of the transistor in the transmitter circuit 140, and the receiver electrodes 153 and 156 are electrically connected to a gate electrode of the transistor in the receiver circuit 150. An input signal is electrically coupled to a gate electrode of the transistor in the transmitter circuit 140, and the source terminal of the transistor in the transmitter circuit 140 is electrically grounded. Further, a drain terminal of the transistor in the receiver circuit 150 outputs an output signal, and the source terminal of the transistor in the receiver circuit 150 is electrically grounded.

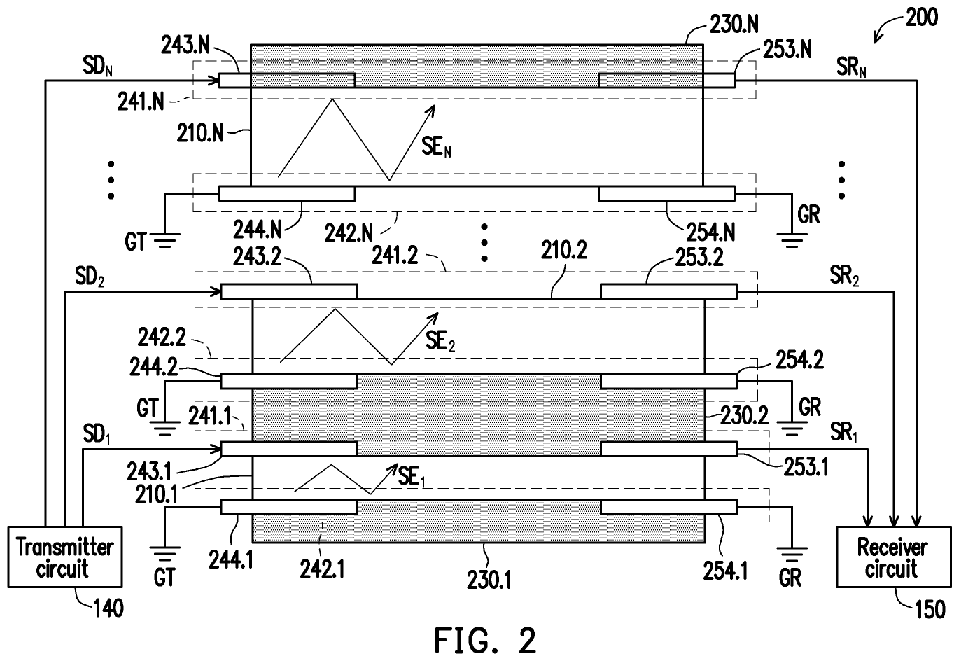

Please note that the number of dielectric waveguide channels shown in FIG. 1A or FIG. 1B is for illustrative purposes only, and is not intended to limit the scope of the present disclosure. In the embodiment shown in FIG. 2, the semiconductor structure 200 includes N dielectric waveguides 210.1-210.N, N first metal layers 241.1-241.N and N second metal layers 242.1-242.N, wherein N is an integer greater than one. The dielectric waveguides 210.1-210.N are disposed one above another and spatially separated from each other. By way of example but not limitation, the semiconductor structure 200 can further include a plurality of ILD layers 230.1-230.M interleaved with the dielectric waveguides 210.1-210.N, wherein M is an integer greater than one. In some embodiments, each dielectric waveguide is disposed between two ILD layers such that M is equal to N+1. In some embodiments, there may be more than one ILD layer disposed between two consecutive dielectric waveguides.

In some embodiments, an electromagnetic signal guided by a first dielectric waveguide of the dielectric waveguides 210.1-210.N, i.e., one of electromagnetic signals SE1-SEN, can be different in frequency from an electromagnetic signal guided by a second dielectric waveguide of the dielectric waveguides 210.1-210.N, i.e., another of the electromagnetic signals SE1-SEN. By way of example but not limitation, a dielectric constant of one dielectric waveguide is different from a dielectric constant of another dielectric waveguide, and/or a thickness of the one dielectric waveguide is different from a thickness of the other dielectric waveguide. As a result, the electromagnetic signal guided by the first dielectric waveguide and the electromagnetic signal guided by the second dielectric waveguide can have different frequencies.

In the embodiment shown in FIG. 2, an ILD layer of the ILD layers 230.1-230.M, a dielectric waveguide disposed over the ILD layer, and a dielectric waveguide disposed below the ILD layer can respectively represent exemplary embodiments of the ILD layer 130, the first dielectric waveguide 110 and the second dielectric waveguide 120 as described above in FIG. 1A and FIG. 1B. As such, each of the dielectric waveguides 210.1-210.N can be configured to transmit data carried in a driver signal, i.e., one of the driver signals SD1-SDN, generated by the transmitter circuit 140 to the receiver circuit 150 through corresponding transmitter and receiver coupling structures disposed within in metal layers, allowing a receiver signal, i.e., one of the receiver signals SR1-SRN, carrying the transmitted data to be provided for the receiver circuit 150.

In some embodiments, a dielectric constant of each dielectric waveguide is greater than a dielectric constant of an ILD layer located on the first side of the dielectric waveguide and a dielectric constant of an ILD layer located on the second side of the dielectric waveguide. For example, a dielectric constant of the dielectric waveguide 210.1 is greater than a dielectric constant of the ILD layer 241.1 and a dielectric constant of the ILD layer 242.1. Hence, electromagnetic radiation introduced into the dielectric waveguide 210.1 can be effectively confined within the dielectric waveguide 210.1 by total internal reflection, and guided from a transmission end portion to a receiver end portion of the dielectric waveguide 210.

In the embodiment shown in FIG. 2, each of the dielectric waveguides 210.1-210.N has a rectangular cross-section, a first side and a second side opposite to the first side. The first side and the second side may be an upper side and a lower side respectively. The first metal layers 241.1-241.N are disposed along respective first sides of the dielectric waveguides 210.1-210.N, respectively, and the second metal layers 242.1-242.N disposed along respective second sides of the dielectric waveguides 210.1-210.N, respectively. Each of the first metal layers 241.1-241.N may include a first transmitter electrode, i.e., one of transmitter electrodes 243.1-243.N, and a first receiver electrode, i.e., one of receiver electrodes 253.1-253.N, separated from each other. The first transmitter electrode is coupled to the transmitter circuit 140, and the first receiver electrode is coupled to the receiver circuit 150. Each of the second metal layers 242.1-242.N may include a second transmitter electrode, i.e., one of transmitter electrodes 244.1-244.N, and a second receiver electrode, i.e., one of receiver electrodes 254.1-254.N, separated from each other, the second transmitter electrode is coupled to a transmitter ground GT, and the second receiver electrode is coupled to a receiver ground GR.

In some embodiments, one of the first metal layers 241.1-241.N can represent an exemplary embodiment of the metal layer within which the transmitter electrode 143 and the receiver electrode 153 as described above in FIG. 1A and FIG. 1B are disposed, and one of the second metal layers 242.1-242.N can represent an exemplary embodiment of the metal layer within which the transmitter electrode 144 and the receiver electrode 154 as described above in FIG. 1A and FIG. 1B are disposed. As such, the first transmitter electrode and the first receiver electrode disposed along the first side of one of the dielectric waveguides 210.1-210.N can represent exemplary embodiments of the transmitter electrode 143 and the receiver electrode 153 as described above in FIG. 1A and FIG. 1B, and the second transmitter electrode and the second receiver electrode disposed along the second side of one of the dielectric waveguides 210.1-210.N can represent exemplary embodiments of the transmitter electrode 144 and the receiver electrode 154 as described above in FIG. 1A and FIG. 1B.

In some embodiments, one of the first metal layers 241.1-241.N can represent an exemplary embodiment of the metal layer within which the transmitter electrode 146 and the receiver electrode 156 as described above in FIG. 1A and FIG. 1B are disposed, and one of the second metal layers 242.1-242.N can represent an exemplary embodiment of the metal layer within which the transmitter electrode 147 and the receiver electrode 157 as described above in FIG. 1A and FIG. 1B are disposed. As such, the first transmitter electrode and the first receiver electrode disposed along the first side of one of the dielectric waveguides 210.1-210.N can represent exemplary embodiments of the transmitter electrode 146 and the receiver electrode 156 as described above in FIG. 1A and FIG. 1B, and the second transmitter electrode and the second receiver electrode disposed along the second side of one of the dielectric waveguides 210.1-210.N can represent exemplary embodiments of the transmitter electrode 147 and the receiver electrode 157 as described above in FIG. 1A and FIG. 1B.

In some embodiments, the dielectric waveguides 210.1-210.N can be fabricated in an interposer (e.g., a silicon interposer, an organic interposer, or the like) of a Chip-on-Wafer-on Substrate (CoWoS) type package.

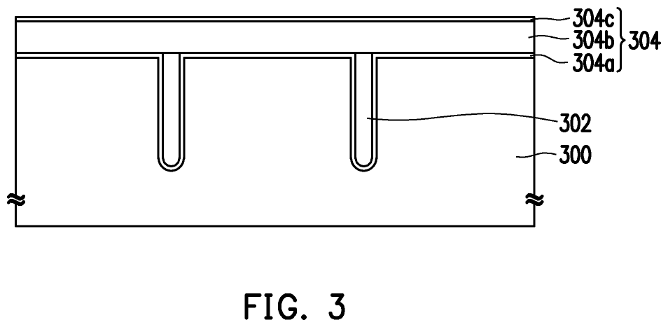

FIGS. 3 through 15 schematically illustrates a process flow for fabricating an interposer.

Referring to FIG. 3, a semiconductor substrate 300 including through semiconductor vias (TSVs) 302 formed therein is provided. As illustrated in FIG. 3, the through semiconductor vias 302 have height smaller than the thickness of the semiconductor substrate 300. The semiconductor substrate 300 may have a thickness of about 750 micrometers. In some embodiments, the semiconductor substrate 300 is a bulk semiconductor substrate, such as a semiconductor wafer. For example, the semiconductor substrate 300 includes silicon or other elementary semiconductor materials such as germanium. The semiconductor substrate 300 may be an un-doped or doped (e.g., p-type, n-type, or a combination thereof) semiconductor substrate. In some embodiments, the semiconductor substrate 300 includes an epitaxially grown semiconductor layer on a dielectric layer. The epitaxially grown semiconductor layer may be made of silicon germanium, silicon, germanium, one or more other suitable materials, or a combination thereof.

A dielectric stack 304 may be formed over the top surface of the semiconductor substrate 300 to cover the top surfaces of the through semiconductor vias 302. The dielectric stack 304 may include a bottom dielectric layer 304a, a middle dielectric layer 304b and an upper dielectric layer 304c, wherein the bottom dielectric layer 304a may include a silicon nitride (SiNₓ) layer, the middle dielectric layer 304b may include an undoped silicon glass (USG) layer, and the upper dielectric layer 304c may include a silicon oxynitride (SiONₓ) layer. The bottom dielectric layer 304a, the middle dielectric layer 304b and the upper dielectric layer 304c are sequentially formed over the semiconductor substrate 300 through plasma enhanced chemical vapor deposition (PECVD) processes, and the process temperature of the PECVD processes may range from about 400 Celsius degrees to about 420 Celsius degrees. The bottom dielectric layer 304a (e.g., silicon nitride layer may have a thickness of about 500 angstroms, the middle dielectric layer 304b (e.g., undoped silicon glass layer) may have a thickness of about 9000 angstroms, and the upper dielectric layer 304c (e.g., silicon oxynitride layer) may have a thickness of about 600 angstroms.

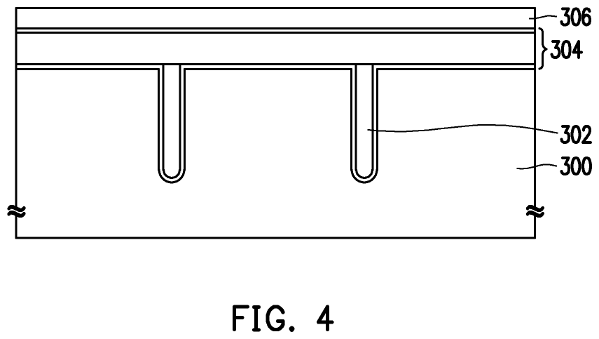

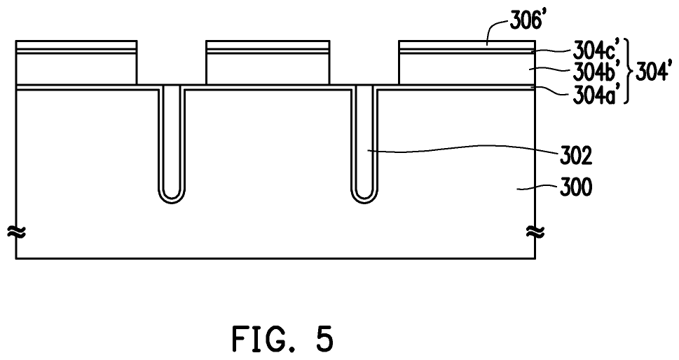

Referring to FIG. 4 and FIG. 5, a photoresist material layer 306 is formed over the dielectric stack 304 through a spin-coating process, for example. The photoresist material layer 306 may entirely covers the top surface of the dielectric stack 304. The photoresist material layer 306 is then patterned through a photolithography process such that a patterned photoresist layer 306′ is formed on the dielectric stack 304, and portions of the dielectric stack 304 are revealed by the patterned photoresist layer 306′. The revealed portions of the dielectric stack 304 may be removed through an etch process by using the patterned photoresist layer 306′ as a mask such that a patterned dielectric stack 304′ covered by the patterned photoresist layer 306′ is formed on the semiconductor substrate 300. As illustrated in FIG. 5, the patterned dielectric stack 304′ may includes trenches located above the through semiconductor vias 302 such that the through semiconductor vias 302 may be revealed by the trenches formed in the patterned dielectric stack 304′. In addition, the patterned dielectric stack 304′ includes a bottom dielectric layer 304a′, a middle dielectric layer 304b′ and an upper dielectric layer 304c′.

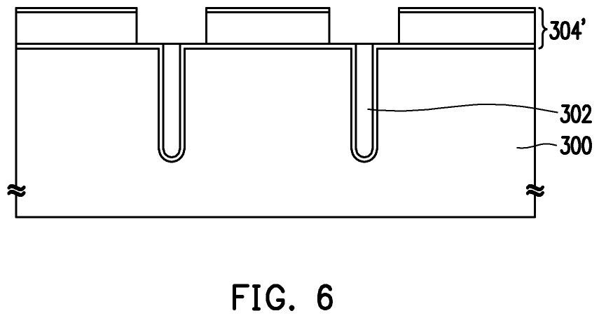

Referring to FIG. 6, the patterned photoresist layer 306′ is removed until the top surface of the patterned dielectric stack 304′ are revealed. In some embodiments, the removal process of the patterned photoresist layer 306′ includes an ash process or other suitable removal processes.

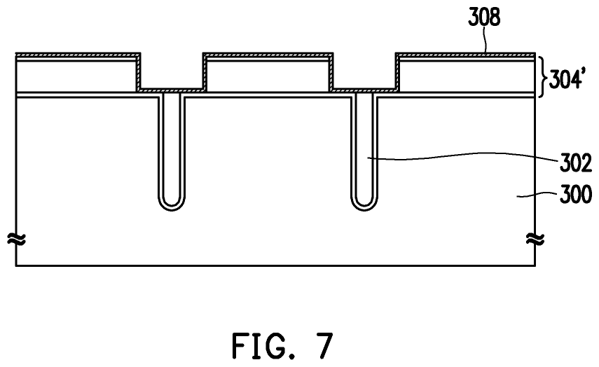

Referring to FIG. 7, a seed layer 308 is formed over the semiconductor substrate 300 to cover the patterned dielectric stack 304′ formed over the semiconductor substrate 300. The seed layer 308 may conformally cover the top surface of the patterned dielectric stack 304′, sidewalls of the patterned dielectric stack 304′, the top surfaces of the through semiconductor vias 302 as well as the revealed portions of the semiconductor substrate 300 that are not covered by the patterned dielectric stack 304′. The seed layer 308 may be formed through a sputtering process or other suitable deposition processes. In some embodiments, the seed layer 308 is a sputtered titanium/copper (Ti/Cu) laminated layer, wherein the titanium layer of the seed layer 308 has a thickness of about 500 angstroms, and the copper layer of the seed layer 308 has a thickness of about 500 angstroms. In some other embodiments, the seed layer 308 includes a tantalum nitride/tantalum (TaN/Ta) barrier layer and a copper layer covering the TaN/Ta barrier layer, wherein the TaN/Ta barrier layer of the seed layer 308 is formed by chemical vapor deposition and has a thickness of about 300 angstroms, and the copper layer of the seed layer 308 is formed by physical vapor deposition and has a thickness of about 1550 angstroms.

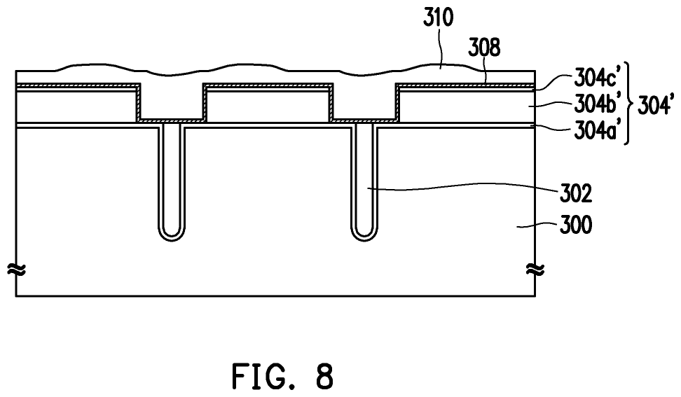

Referring to FIG. 8, after forming the seed layer 308, the semiconductor substrate 300 including the patterned dielectric stack 304′ and the seed layer 308 formed thereon may be immersed into a plating solution of a plating bath such that the conductive material 310 is plated on the portions of the seed layer. As illustrated in FIG. 8, the conductive material 310 fills the trenches defined in the patterned dielectric stack 304′. In other words, the top surface of the conductive material 310 is higher than that top surface of the patterned dielectric stack 304′. For example, the thickness of the conductive material 310 ranges from about 1100 angstroms to about 1400 angstroms.

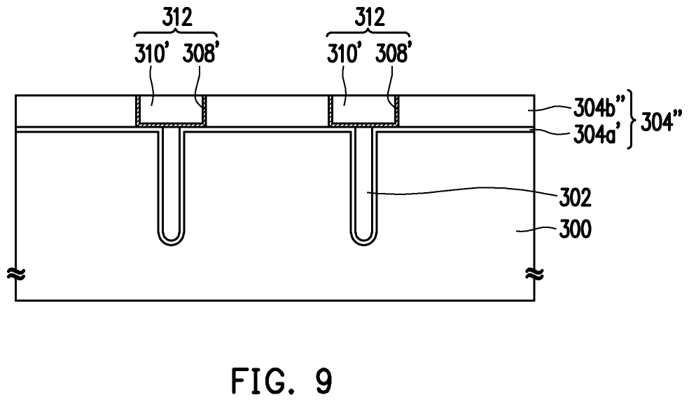

Referring to FIG. 8 and FIG. 9, after the conductive material 310 is formed over the semiconductor substrate 300, a planarization process may be performed to remove excess portions of the conductive material 310 (i.e., excess conductive material located outside the trenches defined in the patterned dielectric stack 304′), the seed layer 308 and a portion of the patterned dielectric stack 304′ such that a patterned dielectric stack 304″ including the bottom dielectric layer 304a′ and a dielectric layer 304b″ is formed. In some embodiments, the seed layer 308, the upper dielectric layer 304c′ and a portion of the middle dielectric layer 304b′ of the patterned dielectric stack 304′ are removed during the planarization process. For example, the remaining thickness of the middle dielectric layer 304b′ is about 7000 angstroms while the thickness of the bottom dielectric layer 304a′ is about 500 angstroms. The planarization process may include a chemical mechanical polishing (CMP) process, a mechanical grinding process, an etching process, a combination thereof, or the like. After performing the planarization process, conductive wirings 312 are formed in the trenches defined by the patterned dielectric stack 304″. The conductive wirings 312 are electrically connected to the through semiconductor vias 302, and each of the conductive wirings 312 includes a seed pattern 308′ and a conductive material 310′ respectively. The thickness of the conductive wirings 312 is substantially equal to the thickness of the patterned dielectric stack 304″. The thickness of the conductive wirings 312 and the thickness of the patterned dielectric stack 304″ may be about 7500 angstroms.

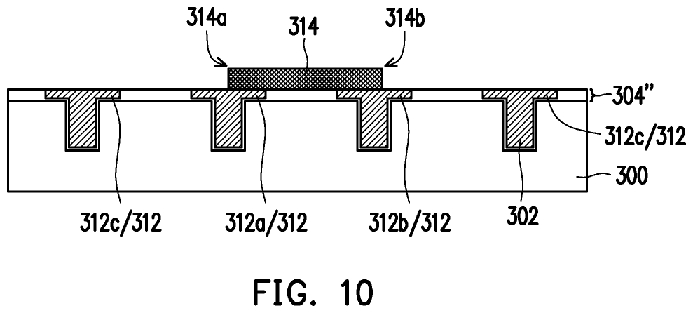

Referring to FIG. 10, the conductive wirings 312 embedded in the patterned dielectric stack 304″ may include a transmitter electrode 312a, a receiver electrode 312b and electrical signal wirings 312c. In some embodiments, the transmitter electrode 312a is laterally separated from the receiver electrode 312b by the patterned dielectric stack 304″. The transmitter electrode 312a and the receiver electrode 312b are electrically connected to a transmitter ground GT and a receiver ground GR respectively, such as the transmitter ground GT and the receiver ground GR shown in FIG. 1A, FIG. 1B and FIG. 2.

As illustrated in FIG. 10, a dielectric waveguide 314 is formed overlying the transmitter electrode 312a, the receiver electrode 312b and a portion of the patterned dielectric stack 304″. The dielectric waveguide 314 may be formed by a photolithography process following by an etching process. The dielectric waveguide 314 includes a transmission end portion 314a and a receiver end portion 314b, wherein the transmission end portion 314a lands on the transmitter electrode 312a, and the receiver end portion 314b lands on the receiver electrode 312b. The transmission end portion 314a is in contact with the transmitter electrode 312a, and the receiver end portion 314b is in contact with the receiver electrode 312b. The dielectric waveguide 314 may include a higher dielectric constant than the patterned dielectric stack 304″. The dielectric waveguide 314 may be formed through a PVD process or a CVD process. In some embodiments, the material of the dielectric waveguide 314 includes titanium oxide (TiO₂), SrTiO₃ (STO), PbZrTiO₃ (PZT), BaSrTiO₃ (BST) or BaTiO₃ (BTO). In an embodiment where the dielectric waveguide 314 includes titanium oxide (TiO₂), the dielectric constant (k) of titanium oxide (TiO₂) is about 83, and the minimum height of the titanium oxide (TiO₂) is about 35 micrometers when data rate and bandwidth requirement is about 25 GBPS. In an embodiment where the dielectric waveguide 314 includes SrTiO₃ (STO), the dielectric constant (k) of SrTiO₃ (STO) is about 200, and the minimum height of the SrTiO₃ (STO) is about 12 micrometers when data rate and bandwidth requirement is about 25 GBPS. In an embodiment where the dielectric waveguide 314 includes PbZrTiO₃ (PZT), the dielectric constant (k) of PbZrTiO₃ (PZT) ranges from about 1000 to about 1500, and the minimum height of PbZrTiO₃ (PZT) is about 2.5 micrometers when data rate and bandwidth requirement is about 25 GBPS. In an embodiment where the dielectric waveguide 314 includes BaSrTiO₃ (BST), the dielectric constant (k) of BaSrTiO₃ (BST) ranges from about 250 to about 12000, and the minimum height of the BaSrTiO₃ (BST) is about 7.2 micrometers when data rate and bandwidth requirement is about 25 GBPS. In an embodiment where the dielectric waveguide 314 includes BaTiO₃ (BTO), the dielectric constant (k) of BaTiO₃ (BTO) is about 500, and the minimum height of BaTiO₃ (BTO) is about 5 micrometers when data rate and bandwidth requirement is about 25 GBPS. In the above-mentioned embodiments, the minimum height of dielectric waveguide 314 is below 18 micrometers which is feasible in processes and provides larger process window. The afore-mentioned materials are given for illustrative purposes. Various materials of the dielectric waveguide 314 are within the contemplated scoped of the present disclosure.

In applications for 25 GHz clock frequency (i.e., 25 GBPS) of chiplet interconnect (i.e., interconnect between the semiconductor dies), the dielectric waveguide 314 may be a 2-channel waveguide, the dielectric waveguide 314 includes BaSrTiO₃ (BST), the dielectric constant (k) of BaSrTiO₃ (BST) waveguide is about 230, and the heights of the 2-channel BaSrTiO₃ (BST) waveguide are 7.2 micrometers and 14.4 micrometers respectively.

In applications for 25 GHz clock frequency (i.e., 25 GBPS) of chiplet interconnect, the dielectric waveguide 314 may be a 3-channel waveguide, the dielectric waveguide 314 includes BaTiO₃ (BTO), the dielectric constant (k) of BaTiO₃ (BTO) waveguide is about 500, and the heights of the 3-channel BaTiO₃ (BTO) waveguide are 5 micrometers, 10 micrometers and 15 micrometers respectively.

In applications for 25 GHz clock frequency (i.e., 25 GBPS) of chiplet interconnect, the dielectric waveguide 314 may be a 6-channel waveguide, the dielectric waveguide 314 includes PbZrTiO₃ (PZT), the dielectric constant (k) of PbZrTiO₃ (PZT) waveguide is about 1000, and the heights of the 6-channel PbZrTiO₃ (PZT) waveguide are 2.5 micrometers, 5 micrometers, 7.5 micrometers, 10 micrometers, 12.5 micrometers and 15 micrometers respectively.

In applications for 50 GHz clock frequency (i.e., 50 GBPS) of chiplet interconnect, the dielectric waveguide 314 may be a 1-channel waveguide, the dielectric waveguide 314 includes titanium oxide (TiO₂), the dielectric constant (k) of titanium oxide (TiO₂) waveguide is about 17.5, and the height of the 1-channel titanium oxide (TiO₂) waveguide is about 17.5 micrometers.

In applications for 50 GHz clock frequency (i.e., 50 GBPS) of chiplet interconnect, the dielectric waveguide 314 may be a 4-channel waveguide, the dielectric waveguide 314 includes BaSrTiO₃ (BST), the dielectric constant (k) of BaSrTiO₃ (BST) waveguide is about 230, and the heights of the 4-channel BaSrTiO₃ (BST) waveguide are 3.6 micrometers, 7.2 micrometers, 10.8 micrometers and 14.4 micrometers respectively.

In applications for 50 GHz clock frequency (i.e., 50 GBPS) of chiplet interconnect, the dielectric waveguide 314 may be a 6-channel waveguide, the dielectric waveguide 314 includes BaTiO₃ (BTO), the dielectric constant (k) of BaTiO₃ (BTO) waveguide is about 500, and the heights of the 6-channel BaTiO₃ (BTO) waveguide are 2.5 micrometers, 5 micrometers, 7.5 micrometers, 10 micrometers, 12.5 micrometers, and 15 micrometers respectively.

In applications for 50 GHz clock frequency (i.e., 50 GBPS) of chiplet interconnect, the dielectric waveguide 314 may be a 12-channel waveguide, the dielectric waveguide 314 includes PbZrTiO₃ (PZT), the dielectric constant (k) of PbZrTiO₃ (PZT) waveguide is about 1000, and the heights of the 12-channel PbZrTiO₃ (PZT) waveguide are 1.25 micrometers, 2.5 micrometers, 3.75 micrometers, 5 micrometers, 6.25 micrometers, 7.5 micrometers, 8.75 micrometers, 10 micrometers, 11.25 micrometers, 12.5 micrometers, 13.75 micrometers, and 15 micrometers respectively.

In applications for 100 GHz clock frequency (i.e., 100 GBPS) of chiplet interconnect, the dielectric waveguide 314 may be a 2-channel waveguide, the dielectric waveguide 314 includes titanium oxide (TiO₂), the dielectric constant (k) of titanium oxide (TiO₂) waveguide is about 17.5, and the heights of the 2-channel titanium oxide (TiO₂) waveguide are 8.75 micrometers and 17.5 micrometers respectively.

In applications for 100 GHz clock frequency (i.e., 100 GBPS) of chiplet interconnect, the dielectric waveguide 314 may be a 8-channel waveguide, the dielectric waveguide 314 includes BaSrTiO₃ (BST), the dielectric constant (k) of BaSrTiO₃ (BST) waveguide is about 230, and the heights of the 8-channel BaSrTiO₃ (BST) waveguide are 1.8 micrometers, 3.6 micrometers, 5.4 micrometers, 7.2 micrometers, 9 micrometers, 10.8 micrometers, 12.6 micrometers, and 14.4 micrometers respectively.

In applications for 100 GHz clock frequency (i.e., 100 GBPS) of chiplet interconnect, the dielectric waveguide 314 may be a 12-channel waveguide, the dielectric waveguide 314 includes BaTiO₃ (BTO), the dielectric constant (k) of BaTiO₃ (BTO) waveguide is about 500, and the heights of the 12-channel BaTiO₃ (BTO) waveguide are 1.25 micrometers, 2.5 micrometers, 3.75 micrometers, 5 micrometers, 6.25 micrometers, 7.5 micrometers, 8.75 micrometers, 10 micrometers, 11.25 micrometers, 12.5 micrometers, 13.75 micrometers, and 15 micrometers respectively.

In applications for 100 GHz clock frequency (i.e., 100 GBPS) of chiplet interconnect, the dielectric waveguide 314 may be a 24-channel waveguide, the dielectric waveguide 314 includes PbZrTiO₃ (PZT), the dielectric constant (k) of PbZrTiO₃ (PZT) waveguide is about 1000, and the heights of the 24-channel PbZrTiO₃ (PZT) waveguide are 0.625 micrometers, 1.25 micrometers, 1.875 micrometers, 2.5 micrometers, 3.125 micrometers, 3.75 micrometers, 4.375 micrometers, 5 micrometers, 5.625 micrometers, 6.25 micrometers, 6.875 micrometers, 7.5 micrometers, 8.125 micrometers, 8.75 micrometers, 9.375 micrometers, 10 micrometers, 10.625 micrometers, 11.25 micrometers, 11.875 micrometers, 12.5 micrometers, 13.125 micrometers, 13.75 micrometers, 14.375 micrometers, and 15 micrometers respectively.

When the thickness of the dielectric waveguide 314 is fixed at about 2.5 micrometers, BaSrTiO₃ (BST) waveguide may be utilized in 25 GBPS data communication, BaTiO₃ (BTO) waveguide may be utilized in 50 GBPS data communication, and PbZrTiO₃ (PZT) waveguide may be utilized in 100 GBPS data communication. When the thickness of the dielectric waveguide 314 is fixed at about 5 micrometers, BaSrTiO₃ (BST) waveguide may be utilized in 12.5 GBPS data communication, BaTiO₃ (BTO) waveguide may be utilized in 25 GBPS data communication, and PbZrTiO₃ (PZT) waveguide may be utilized in 50 GBPS data communication. When the thickness of the dielectric waveguide 314 is fixed at about 10 micrometers, BaSrTiO₃ (BST) waveguide may be utilized in 3.25 GBPS data communication, BaTiO₃ (BTO) waveguide may be utilized in 12.5 GBPS data communication, and PbZrTiO₃ (PZT) waveguide may be utilized in 25 GBPS data communication. In other words, BaSrTiO₃ (BST) waveguide, BaTiO₃ (BTO) waveguide and PbZrTiO₃ (PZT) waveguide may be formed in at least one semiconductor die of a package structure to transmit electromagnetic signal having different frequencies.

In some alternative embodiments, the material of the dielectric waveguide 314 includes silicon dioxide (SiO₂), silicon nitride (Si₃N₄), aluminum oxide (Al₂O₃) Y₂O₃, HfO₂ or ZrO₃.

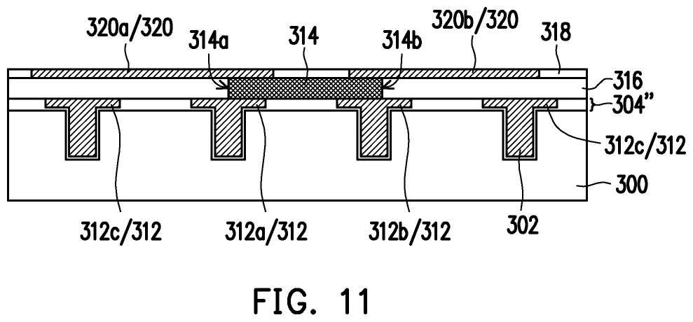

Referring to FIG. 11, after forming the dielectric waveguide 314, an inter-level dielectric (ILD) layer 316 is formed over the patterned dielectric stack 304″ such that the dielectric waveguide 314 is embedded in the patterned dielectric stack 304″. The top surface of the dielectric waveguide 314 may be substantially level with the top surface of the ILD layer 316. In some embodiments, the ILD layer 316 includes a silicon dioxide layer, or the like. The ILD layer 316 may be formed through a deposition process followed by a planarization process. The planarization process for forming the ILD layer 316 may include a chemical mechanical polishing (CMP) process, a mechanical grinding process, an etching process, a combination thereof, or the like.

After forming the ILD layer 316, an ILD layer 318 and conductive wirings 320 formed in trenches defined by the ILD layer 318 are formed to cover the dielectric waveguide 314 and the ILD layer 316. In some embodiments, the ILD layer 318 includes a silicon dioxide layer, or the like. The thickness of the conductive wirings 320 is substantially equal to the thickness of the ILD layer 318. The thickness of the conductive wirings 320 and the thickness of the ILD layer 318 may be about 7500 angstroms. The ILD layer 318 may be formed through a deposition process followed by a patterning process. The patterning process for forming the ILD layer 318 may include photolithography process following by an etching process. The conductive wirings 320 may be formed through a deposition process followed by a planarization process. The planarization process for forming the conductive wirings 320 may include a chemical mechanical polishing (CMP) process, a mechanical grinding process, an etching process, a combination thereof, or the like. The fabrication process of the conductive wirings 320 may be similar with that of the conductive wirings 312, and the detailed descriptions are thus omitted.

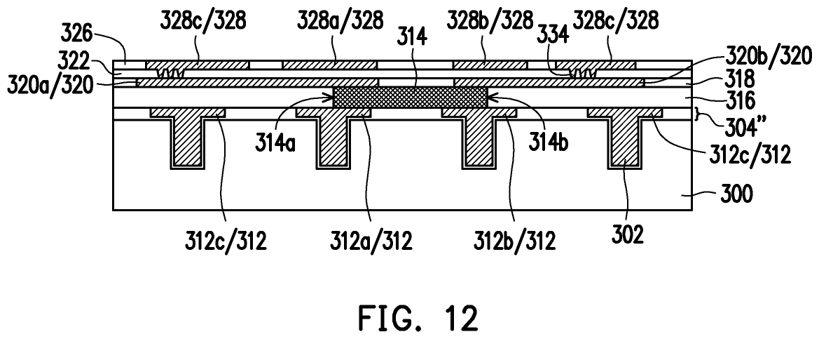

As illustrated in FIG. 11, the conductive wirings 320 embedded in the ILD layer 318 may include a transmitter electrode 320a and a receiver electrode 320b. The transmitter electrode 320a is located above the transmitter 312a, and the receiver electrode 320b is located above the receiver electrode 312b. The transmission end portion 314a of the dielectric waveguide 314 is in contact with the transmitter electrode 320a, and the receiver end portion 314b of the dielectric waveguide 314 is in contact with the receiver electrode 320b. The conductive wirings 320 may further include other electrical signal wirings (not shown in FIG. 11) embedded in the ILD layer 318. In some embodiments, the transmitter electrode 320a is laterally separated from the receiver electrode 320b by the ILD layer 318. Through subsequentially formed conductors (e.g., conductors shown in FIG. 12 through FIG. 15), the transmitter electrode 320a and the receiver electrode 320b can electrically connect to a transmitter circuit and a receiver circuit respectively, such as the transmitter circuit 140 and the receiver circuit 150 shown in FIG. 1A, FIG. 1B and FIG. 2. The transmitter electrode 312a and the transmitter electrode 320a constitute a transmitter coupling structure, such as the transmitter coupling structure 142 shown in FIG. 1A and FIG. 1B. The receiver electrode 312b and the receiver electrode 320b constitute a receiver coupling structure, such as the receiver coupling structure 152 shown in FIG. 1A and FIG. 1B.

Referring to FIG. 12, an ILD layer 322 and conductive vias 324 embedded in the ILD layer 322 are formed to cover the ILD layer 318 and the conductive wirings 320. The height of the conductive vias 324 is substantially equal to the thickness of the ILD layer 322. In some embodiments, the ILD layer 322 includes a silicon dioxide layer, or the like. The ILD layer 322 may be formed through a deposition process followed by a patterning process. The patterning process for forming the ILD layer 322 may include photolithography process following by an etching process. The conductive vias 324 may be formed through a deposition process followed by a planarization process. The planarization process for forming the conductive vias 324 may include a chemical mechanical polishing (CMP) process, a mechanical grinding process, an etching process, a combination thereof, or the like.

After forming the ILD layer 322 and the conductive vias 324, an ILD layer 326 and conductive wirings 328 formed in trenches defined by the ILD layer 326 are formed to cover the ILD layer 322 and the conductive vias 324. The thickness of the conductive wirings 328 is substantially equal to the thickness of the ILD layer 326. The conductive wirings 328 are electrically connected to the conductive vias 324. In some embodiments, the ILD layer 326 includes a silicon dioxide layer, or the like. The ILD layer 326 may be formed through a deposition process followed by a patterning process. The patterning process for forming the ILD layer 326 may include photolithography process following by an etching process. The conductive wirings 328 may be formed through a deposition process followed by a planarization process. The planarization process for forming the conductive wirings 328 may include a chemical mechanical polishing (CMP) process, a mechanical grinding process, an etching process, a combination thereof, or the like. The fabrication process of the conductive wirings 328 may be similar with that of the conductive wirings 312, and the detailed descriptions are thus omitted.

As illustrated in FIG. 12, the conductive wirings 328 embedded in the ILD layer 326 may include a transmitter electrode 328a, a receiver electrode 328b and electrical signal wirings 328c. In some embodiments, the transmitter electrode 328a is laterally separated from the receiver electrode 328b by the ILD layer 326. The transmitter electrode 328a and the receiver electrode 328b are electrically connected to a transmitter ground GT and a receiver ground GT respectively, such as the transmitter ground GT and the receiver ground GR shown in FIG. 1A, FIG. 1B and FIG. 2.

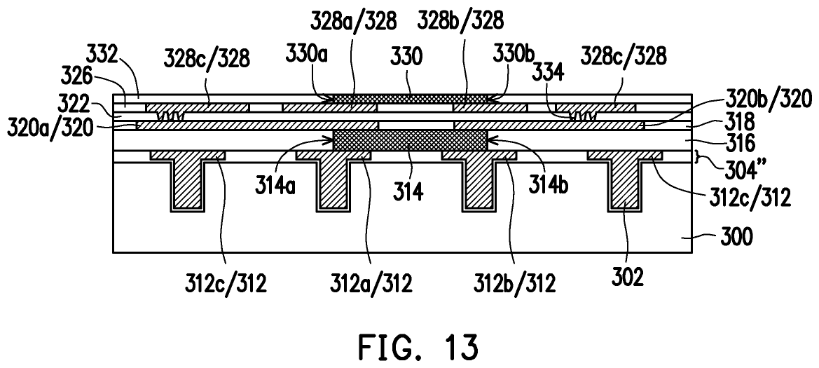

Referring to FIG. 13, a dielectric waveguide 330 is formed overlying the transmitter electrode 328a, the receiver electrode 328b and a portion of the ILD 326. The dielectric waveguide 330 may be formed by a photolithography process following by an etching process. The dielectric waveguide 330 includes a transmission end portion 330a and a receiver end portion 330b, wherein the transmission end portion 330a lands on the transmitter electrode 328a, and the receiver end portion 330b lands on the receiver electrode 328b. The transmission end portion 330a is in contact with the transmitter electrode 328a, and the receiver end portion 330b is in contact with the receiver electrode 328b. The dielectric waveguide 330 may include a higher dielectric constant than the ILD layer 326. The dielectric waveguide 330 may be formed through a PVD process or a CVD process. In some embodiments, the material of the dielectric waveguide 330 includes titanium oxide (TiO₂), SrTiO₃ (STO), PbZrTiO₃ (PZT), BaSrTiO₃ (BST) or BaTiO₃ (BTO). In an embodiment where the dielectric waveguide 330 includes titanium oxide (TiO₂), the dielectric constant (k) of titanium oxide (TiO₂) is about 83, and the minimum height of the titanium oxide (TiO₂) is about 35 micrometers when data rate and bandwidth requirement is about 25 GBPS. In an embodiment where the dielectric waveguide 330 includes SrTiO₃ (STO), the dielectric constant (k) of SrTiO₃ (STO) is about 200, and the minimum height of the SrTiO₃ (STO) is about 12 micrometers when data rate and bandwidth requirement is about 25 GBPS. In an embodiment where the dielectric waveguide 330 includes PbZrTiO₃ (PZT), the dielectric constant (k) of PbZrTiO₃ (PZT) is about 1000, and the minimum height of PbZrTiO₃ (PZT) is about 2.5 micrometers when data rate and bandwidth requirement is about 25 GBPS. In an embodiment where the dielectric waveguide 330 includes BaSrTiO₃ (BST), the dielectric constant (k) of BaSrTiO₃ (BST) ranges from about 350 to about 12000, and the minimum height of the BaSrTiO₃ (BST) is about 7.2 micrometers when data rate and bandwidth requirement is about 25 GBPS. In an embodiment where the dielectric waveguide 330 includes BaTiO₃ (BTO), the dielectric constant (k) of BaTiO₃ (BTO) is about 500, and the minimum height of BaTiO₃ (BTO) is about 5 micrometers when data rate and bandwidth requirement is about 25 GBPS. In the above-mentioned embodiments, the minimum height of dielectric waveguide 330 is below 18 micrometers (e.g., from about 1 micrometer to about 18 micrometers) which is feasible in processes and provides larger process window. The afore-mentioned materials are given for illustrative purposes. Various materials of the dielectric waveguide 330 are within the contemplated scoped of the present disclosure.

In some embodiments, the electromagnetic signal propagated by the dielectric waveguide 314 is different in frequency from the electromagnetic signal propagated by the dielectric waveguide 330. For 5G millimeter-wave (mm-wave) transmission, the first dielectric waveguide 314 located below the dielectric waveguide 340 can be configured to transmit the electromagnetic signal having a frequency about 5 GHz) while the dielectric waveguide 340 can be configured to transmit the electromagnetic signal having a frequency over 10 GHz. By way of example but not limitation, a dielectric constant of the dielectric waveguide 314 is different from (i.e., greater than or smaller than) a dielectric constant of the dielectric waveguide 330. In addition, a thickness of the dielectric waveguide 314 may be different from (i.e., greater than or smaller than) a thickness of the dielectric waveguide 330. As a result, the dielectric waveguide 314 and the dielectric waveguide 330 can be configured to propagate the electromagnetic signals at different frequencies.

As illustrated in FIG. 13, after forming the dielectric waveguide 330, an ILD layer 332 is formed over the ILD 326 and the conductive wirings 328 such that the dielectric waveguide 330 is embedded in the ILD layer 332. The top surface of the dielectric waveguide 330 may be substantially level with the top surface of the ILD layer 332. In some embodiments, the ILD layer 332 includes a silicon dioxide layer, or the like. The ILD layer 332 may be formed through a deposition process followed by a planarization process. The planarization process for forming the ILD layer 332 may include a chemical mechanical polishing (CMP) process, a mechanical grinding process, an etching process, a combination thereof, or the like.

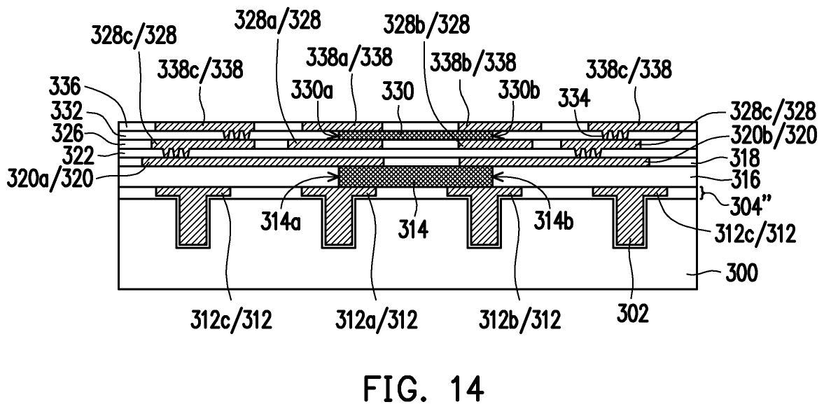

Referring to FIG. 14, conductive vias 334 electrically connected to the conductive wirings 328 are formed in the ILD layer 332. The height of the conductive vias 334 is substantially equal to the thickness of the ILD layer 332. The patterning process for forming the ILD layer 332 may include photolithography process following by an etching process. The conductive vias 334 may be formed through a deposition process followed by a planarization process. The planarization process for forming the conductive vias 334 may include a chemical mechanical polishing (CMP) process, a mechanical grinding process, an etching process, a combination thereof, or the like.

After forming the conductive vias 334, an ILD layer 336 and conductive wirings 338 formed in trenches defined by the ILD layer 336 are formed to cover the ILD layer 332 and the conductive vias 334. The thickness of the conductive wirings 338 is substantially equal to the thickness of the ILD layer 336. The conductive wirings 338 are electrically connected to the conductive vias 334. In some embodiments, the ILD layer 336 includes a silicon dioxide layer, or the like. The ILD layer 336 may be formed through a deposition process followed by a patterning process. The patterning process for forming the ILD layer 336 may include photolithography process following by an etching process. The conductive wirings 338 may be formed through a deposition process followed by a planarization process. The planarization process for forming the conductive wirings 338 may include a chemical mechanical polishing (CMP) process, a mechanical grinding process, an etching process, a combination thereof, or the like. The fabrication process of the conductive wirings 338 may be similar with that of the conductive wirings 312, and the detailed descriptions are thus omitted.

As illustrated in FIG. 14, the conductive wirings 338 embedded in the ILD layer 336 may include a transmitter electrode 338a, a receiver electrode 338b and electrical signal wirings 338c. In some embodiments, the transmitter electrode 338a is laterally separated from the receiver electrode 338b by the ILD layer 336. The transmitter electrode 338a and the receiver electrode 338b are electrically connected to a transmitter ground GT and a receiver ground GR respectively, such as the transmitter ground GT and the receiver ground GR shown in FIG. 1A, FIG. 1B and FIG. 2.

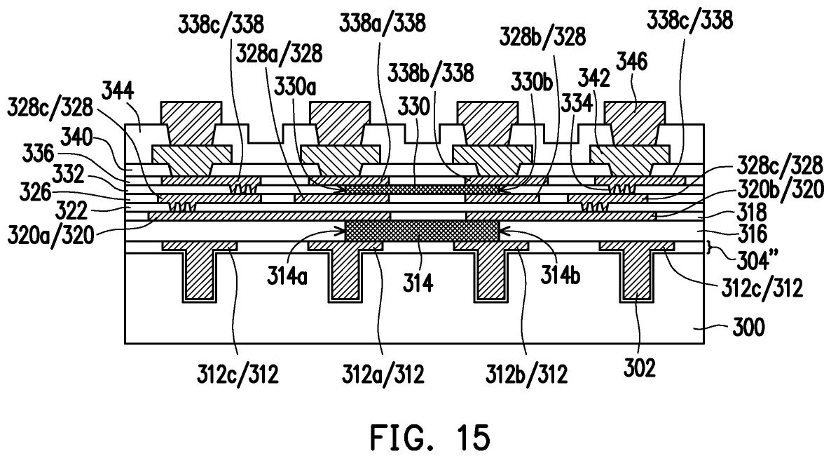

Referring to FIG. 15, an ILD layer 340 is formed to cover the ILD layer 336 and the conductive wirings 338. The ILD layer 340 includes openings for exposing portions of the conductive wirings 338. The ILD layer 340 may be formed through a deposition process followed by a patterning process. The patterning process for forming the ILD layer 340 may include photolithography process following by an etching process. Next, as illustrated in the embodiment shown in FIG. 15, under bump metallurgies (UBMs) 342 are formed to electrically connect to the conductive wirings 338.

As illustrated in FIG. 15, a passivation layer 344 and conductive terminals 346 are formed over the ILD layer 340 and the UBMs 342. The passivation layer 344 includes openings for exposing portions of the UBMs 342. The passivation layer 344 may be formed through a deposition process followed by a patterning process. The patterning process for forming the passivation layer 344 may include photolithography process following by an etching process. In some embodiments, the passivation layer 344 includes a silicon nitride layer formed through a PECVD process. The conductive terminals 346 include micro-bumps disposed on and electrically connected to the UBMs 342. In some embodiments, the conductive terminals 346 include copper micro-bumps or the like.

After forming the conductive terminals 346, a photonic interposer including the embedded dielectric waveguides 314 and 330 are fabricated. In some embodiments, the photonic interposer includes a semiconductor substrate 300 having through vias 302 formed therein and dielectric layers 304″, 316, 318, 322, 326, 332, 336 and 340 stacked on the semiconductor substrate 300, wherein the conductive wirings 312, 320, 324, 328, 334, 338 as well as conductive vias 324 and 334 are embedded in the dielectric layers 304″, 316, 318, 322, 326, 332, 336 and 340.

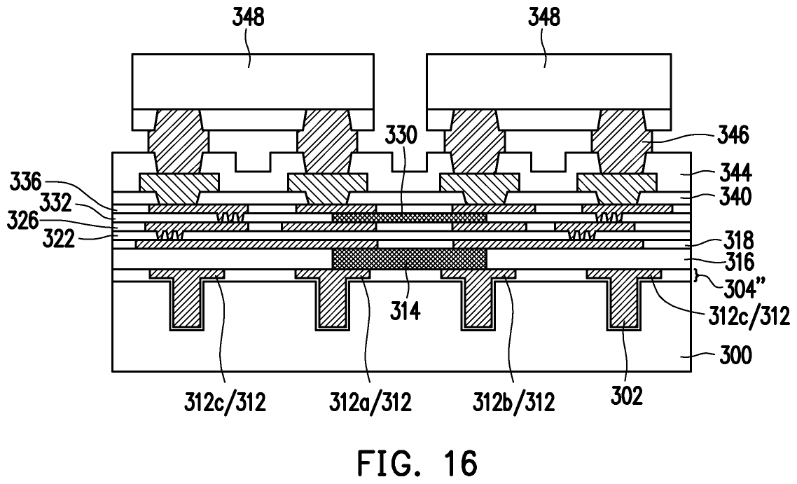

FIGS. 16 through 24 schematically illustrates a process flow for fabricating a package structure including the photonic interposer shown in FIG. 15.

Referring to FIG. 16, after forming the conductive terminals 346, at least one semiconductor die 348 is provided and mounted on the of the photonic interposer. In the present embodiment, two semiconductor dies 348 are provided and mounted on the of the photonic interposer. The number of the semiconductor die 348 is not limited in the present disclosure. As illustrated in FIG. 16, the semiconductor dies 348 are electrically connected to the conductive terminals 346 of the photonic interposer. In some embodiments, each of the semiconductor dies 348 includes a transmitter circuit and a receiver circuit, such as transmitter circuit 140 and a receiver circuit 150 shown in FIG. 1A, FIG. 1B and FIG. 2. In some other embodiments, the semiconductor dies 348 include a transmitter die including a transmitter circuit and a receiver die including a receiver circuit.

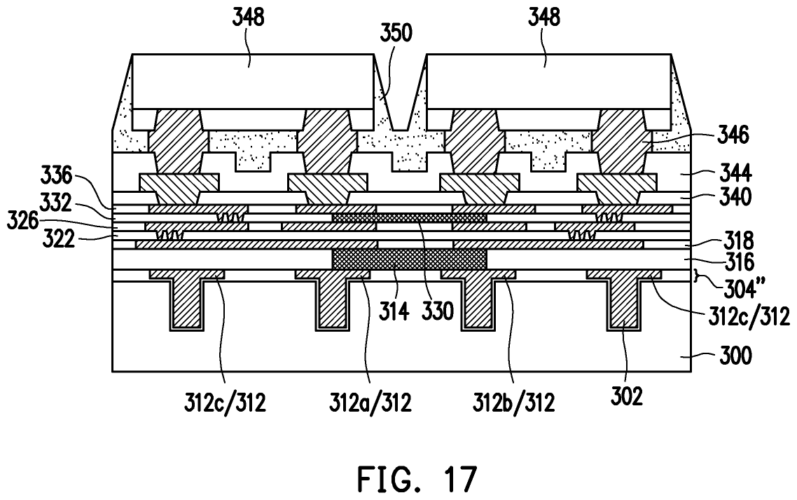

Referring to FIG. 17, an underfill 344 is formed over the photonic interposer to laterally encapsulate the semiconductor dies 348, wherein the conductive terminals 346 are laterally encapsulated by the underfill 344 to ensure reliability of the conductive terminals 346 between the semiconductor dies 348 and the photonic interposer. The underfill 530 may cover at least portions of sidewalls of the semiconductor dies 348 and the top surface of the passivation layer 344. The underfill 350 may include an epoxy resin or the like. The underfill 350 may be formed through a dispensing process.

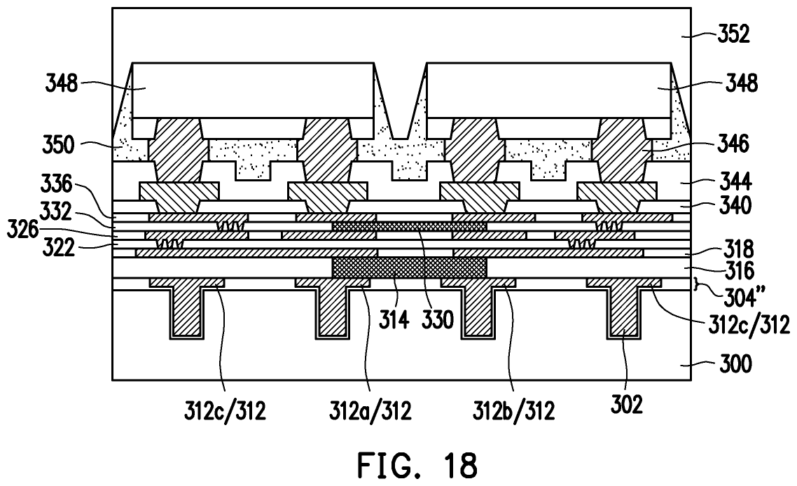

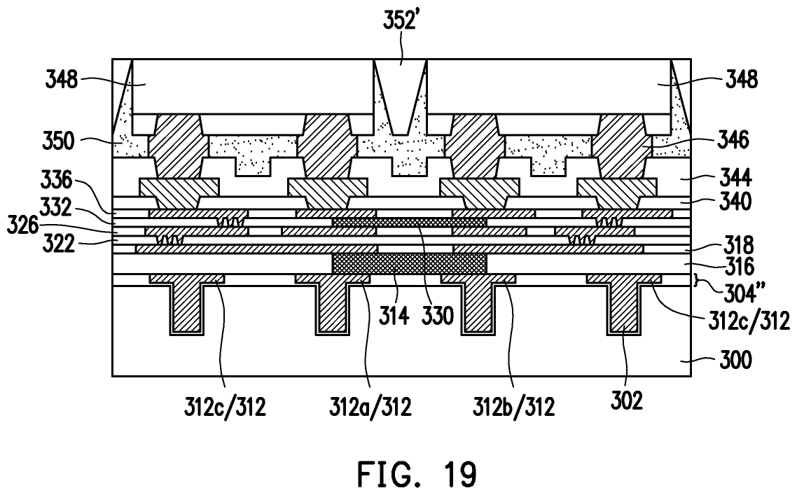

Referring to FIG. 18 and FIG. 19, a molding process may be performed such that an insulating encapsulation material 352 is formed to cover the semiconductor dies 348 and the underfill 350. In some embodiments, the insulating encapsulation material 352 is a molding compound formed through an over-molding process (e.g., compression molding, transfer molding, or the like). As illustrated in FIG. 19, the insulating encapsulation material 352 is then partially removed until the rear surfaces of the semiconductor dies 348 are revealed. The insulating encapsulation material 352 may be partially removed through a CMP process, a mechanical grinding process, an etching process, a combination thereof, or the like. After performing the removal process of the insulating encapsulation material 352, an insulating encapsulant 352′ is formed. The insulating encapsulant 352′ may cover the underfill 350 and fill the gap between the semiconductor dies 348. Furthermore, the top surface of the insulating encapsulant 352′ may be substantially level with the revealed surfaces (e.g., rear surfaces) of the semiconductor dies 348. In some embodiments, the insulating encapsulant 352′ laterally encapsulates the semiconductor dies 348, wherein sidewalls of the insulating encapsulant 352′ are substantially aligned with sidewalls of the photonic interposer, not shown in FIG. 19.

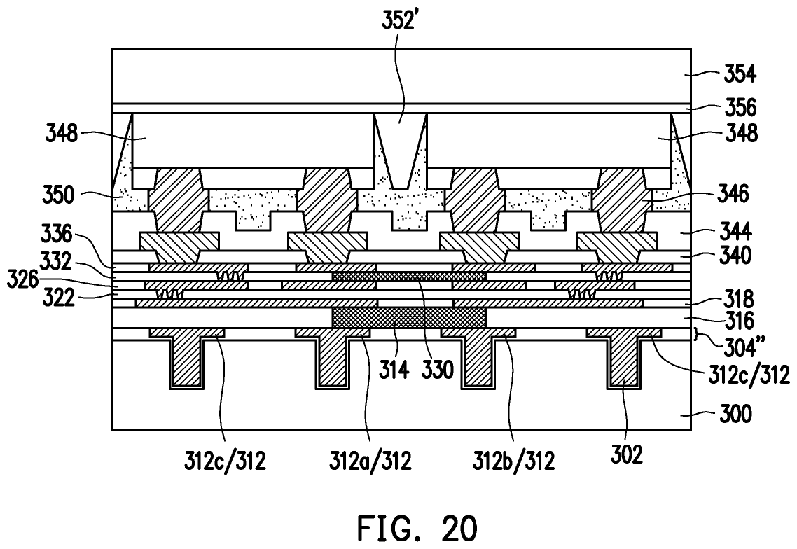

Referring to FIG. 19 and FIG. 20, the resulting structure shown in FIG. 19 is bonded to a carrier 354 through an adhesion layer 356. The rear surfaces of the semiconductor dies 348 and the top surface of the insulating encapsulant 352′ are attached to the carrier 354 through the adhesion layer 356. The carrier 354 may be or include a wafer form substrate, such as a glass substrate, a ceramic substrate, a silicon substrate, or the like. The adhesion layer 356 may be or include a glue layer, a light-to-heat coating (LTHC), an ultraviolet (UV) curable film or the like.

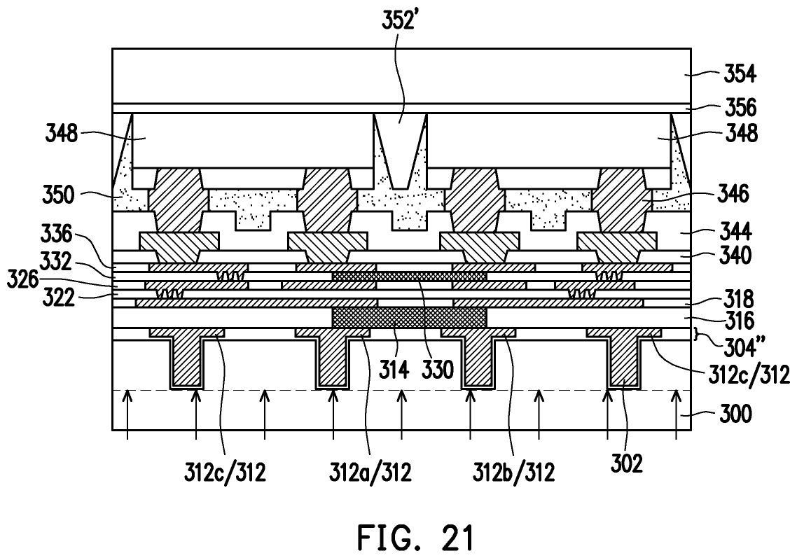

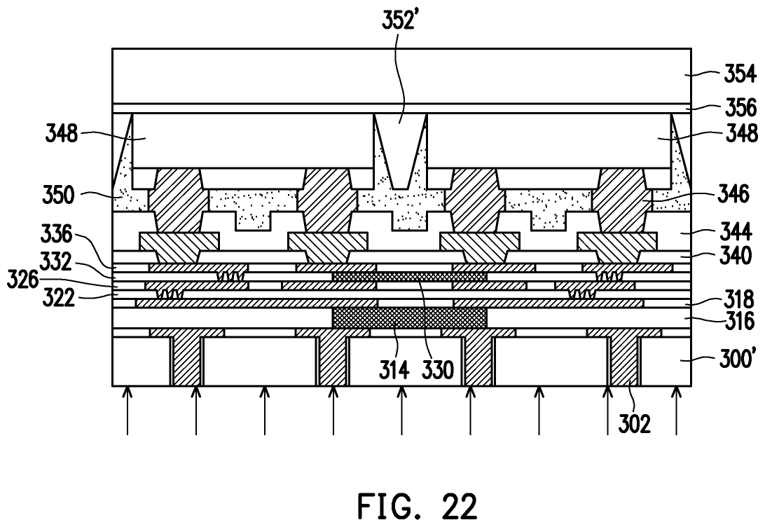

Referring to FIG. 21 and FIG. 22, a thinning process is performed from on the back side of the semiconductor substrate 300 such that the thickness of the semiconductor substrate 300 is reduced and the through semiconductor vias 302 are revealed. The thinning process of the semiconductor substrate 300 may be a CMP process, a mechanical grinding process, an etching process, a combination thereof, or the like. After performing the thinning process of the semiconductor substrate 300, a semiconductor substrate 300′ with reduced thickness is formed and bottom surfaces of the through semiconductor vias 302 are revealed from the back surface of the semiconductor substrate 300′.

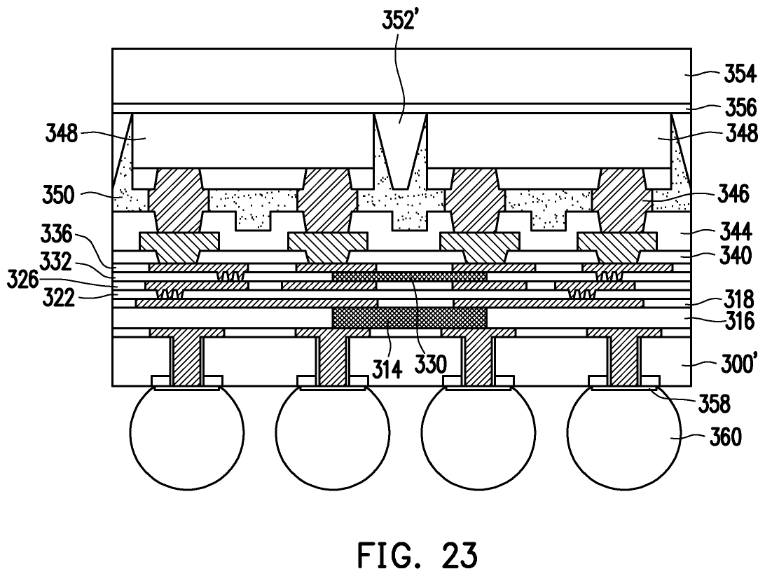

Referring to FIG. 23, conductive pads 358 and conductive terminals 360 are formed on the back surface of the semiconductor substrate 300′. The conductive pads 358 cover the bottom surfaces of the through semiconductor vias 302 and are electrically connected to the through semiconductor vias 302. The conductive terminals 360 are disposed on the conductive pads 358. The conductive pads 358 may be or include balls pads, and the conductive terminals 360 may be or include conductive balls, such as controlled collapse chip connector (C4) bumps.

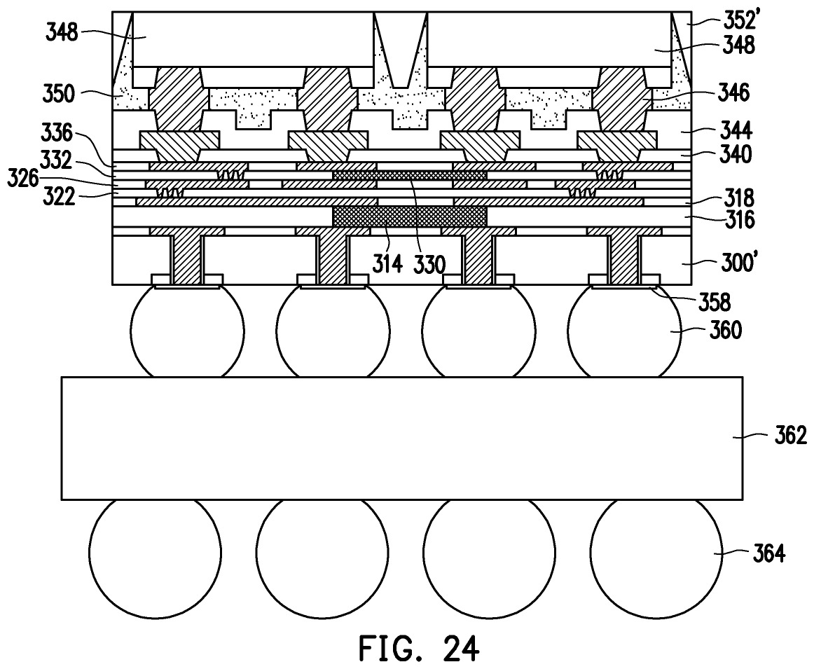

Referring to FIG. 23 and FIG. 24, the carrier 354 and the adhesive layer 356 are then removed from the top surface of the insulating encapsulant 352′ and the rear surfaces of the semiconductor dies 348. In some embodiments, the removal of the adhesive layer 356 is omitted. In other words, the adhesive layer 356 may remain in the resulting package and function as an insulating and protective layer. After removing the carrier 354 and the adhesive layer 356, the resulting structure is mounted onto and electrically connected to a wiring substrate 362 including conductive terminals 364 formed thereon. The wiring substrate 362 is electrically connected the photonic interposer through the conductive terminals 364. In some embodiments, the conductive terminals 364 include conductive balls, such as ball grid array (BGA) balls or the like. The resulting structure shown in FIG. 24 is a Chip-on-Wafer-on Substrate (CoWoS) type package.

The wiring substrate 362 and the semiconductor die 348 are disposed at opposite side of the photonic interposer, wherein the embedded dielectric waveguide 330 is disposed between the embedded dielectric waveguide 314 and the semiconductor die 348, and electromagnetic signals propagated in the embedded dielectric waveguide 330 have higher transmission frequency than electromagnetic signals propagated in the embedded dielectric waveguide 314. Accordingly, better heat dissipation performance can be achieved.

The above illustrations include exemplary operations, but the operations are not necessarily performed in the order shown. Operations may be added, replaced, changed order, and/or eliminated as appropriate, in accordance with the spirit and scope of various embodiments of the present disclosure.

In accordance with some embodiments of the disclosure, a package structure including a wiring substrate, an interposer and a semiconductor die is provided. The interposer is disposed on and electrically connected to the wiring substrate, and the interposer includes an embedded dielectric waveguide. The semiconductor die is disposed on and electrically connected to the interposer. In some embodiments, the interposer includes a semiconductor substrate; dielectric layers stacked on the semiconductor substrate; and conductive wirings disposed on and electrically connected to the semiconductor substrate, wherein the conductive wirings and the embedded dielectric waveguide are embedded in the dielectric layers. In some embodiments, the conductive wirings include a transmitter coupling structure and a receiver coupling structure, the transmitter coupling structure is coupled to a transmission end portion of the embedded dielectric waveguide, and the receiver coupling structure is coupled to a receiver end of the embedded dielectric waveguide. In some embodiments, the transmitter coupling structure includes a pair of transmitter electrodes coupled to the transmission end portion of the embedded dielectric waveguide, and the receiver coupling structure includes a pair of receiver electrodes coupled to the receiver end of the embedded dielectric waveguide. In some embodiments, the pair of transmitter electrodes include a first transmitter electrode and a second transmitter electrode, the first transmitter electrode and the second transmitter electrode are disposed at opposite surfaces of the transmission end portion of the embedded dielectric waveguide, and the pair of receiver electrodes include a first receiver electrode and a second receiver electrode, the first receiver electrode and the second receiver electrode are disposed at opposite surfaces of the receiver end of the embedded dielectric waveguide. In some embodiments, the semiconductor die includes a transmitter circuit and a receiver circuit, the transmitter circuit is electrically connected to the first transmitter electrode, the second transmitter electrode is electrically grounded, the receiver circuit is electrically connected to the first receiver electrode, and the second receiver electrode is electrically grounded. In some embodiments, the package structure further includes first conductive terminals disposed between the interposer and the semiconductor die, wherein the interposer is electrically connected to the semiconductor die through the first conductive terminals; and second conductive terminals disposed between the interposer and the wiring substrate, wherein the interposer is electrically connected the wiring substrate through the second conductive terminals. In some embodiments, the package structure further includes an underfill disposed between the interposer and the semiconductor die, wherein the first conductive terminals are laterally encapsulated by the underfill; and an insulating encapsulant disposed on the interposer, wherein the insulating encapsulant laterally encapsulates the semiconductor die and the underfill. In some embodiments, the semiconductor die includes a transmitter circuit and a receiver circuit, the transmitter circuit is electrically connected to a transmission end portion of the embedded dielectric waveguide, and the receiver circuit is electrically connected to a receiver end of the embedded dielectric waveguide.

In accordance with some other embodiments of the disclosure, a package structure including a photonic interposer, a wiring substrate and a semiconductor die is provided. The photonic interposer includes conductive wirings, a first embedded dielectric waveguide and a second embedded dielectric waveguide. The wiring substrate is electrically connected to the photonic interposer. The semiconductor die is electrically connected to the photonic interposer, the wiring substrate and the semiconductor die are disposed at opposite side of the photonic interposer, wherein the second embedded dielectric waveguide is disposed between the first embedded dielectric waveguide and the semiconductor die, and electromagnetic signals propagated in the second embedded dielectric waveguide have higher transmission frequency than electromagnetic signals propagated in the first embedded dielectric waveguide. In some embodiments, the photonic interposer includes a semiconductor substrate having through vias; and dielectric layers stacked on the semiconductor substrate, wherein the conductive wirings, the first embedded dielectric waveguide and the second embedded dielectric waveguide are embedded in the dielectric layers. In some embodiments, the package structure further includes an insulating encapsulant laterally encapsulating the semiconductor die, wherein sidewalls of the insulating encapsulant are substantially aligned with sidewalls of the photonic interposer. In some embodiments, the semiconductor die includes a transmitter circuit and a receiver circuit, and the conductive wirings include a first transmitter electrode electrically connected to the transmitter circuit, a second transmitter electrode electrically grounded, a first receiver electrode electrically connected to the receiver circuit, and a second receiver electrode electrically grounded. In some embodiments, the first transmitter electrode and the second transmitter electrode are disposed at opposite surfaces of the transmission end portion of the embedded dielectric waveguide, and the first receiver electrode and the second receiver electrode are disposed at opposite surfaces of the receiver end of the embedded dielectric waveguide.

In accordance with some other embodiments of the disclosure, a package structure including a photonic interposer, a wiring substrate and a semiconductor die is provided. The photonic interposer includes conductive wirings and embedded dielectric waveguides coupled to portions of the conductive wirings. The wiring substrate is electrically connected to the photonic interposer. The semiconductor die is electrically connected to the photonic interposer, the wiring substrate and the semiconductor die is disposed at opposite side of the photonic interposer, and the embedded dielectric waveguides are different in transmission frequency. In some embodiments, the photonic interposer includes a semiconductor substrate having through vias; and dielectric layers stacked on the semiconductor substrate, wherein the conductive wirings and the embedded dielectric waveguides are embedded in the dielectric layers. In some embodiments, the package structure further includes an insulating encapsulant laterally encapsulating the semiconductor die, wherein sidewalls of the insulating encapsulant are substantially aligned with sidewalls of the photonic interposer. In some embodiments, the semiconductor die includes a transmitter circuit and a receiver circuit, and the portions of the conductive wirings include a first transmitter electrode electrically connected to the transmitter circuit; a second transmitter electrode electrically grounded; a first receiver electrode electrically connected to the receiver circuit; and a second receiver electrode electrically grounded. In some embodiments, the first transmitter electrode and the second transmitter electrode are disposed at opposite surfaces of the embedded dielectric waveguide, and the first receiver electrode and the second receiver electrode are disposed at opposite surfaces of the embedded dielectric waveguide. In some embodiments, the first transmitter electrode and the first receiver electrode are disposed on a first surface of the embedded dielectric waveguide, and the second transmitter electrode and the second receiver electrode are disposed on a second surface of the embedded dielectric waveguide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a wiring substrate;
an interposer disposed on and electrically connected to the wiring substrate, the interposer comprising an embedded dielectric waveguide; and
a semiconductor die disposed on and electrically connected to the interposer.

2. The package structure of claim 1, wherein the interposer comprises:
a semiconductor substrate;
dielectric layers stacked on the semiconductor substrate; and
conductive wirings disposed on and electrically connected to the semiconductor substrate, wherein the conductive wirings and the embedded dielectric waveguide are embedded in the dielectric layers.

3. The package structure of claim 2, wherein the conductive wirings comprise a transmitter coupling structure and a receiver coupling structure, the transmitter coupling structure is coupled to a transmission end portion of the embedded dielectric waveguide, and the receiver coupling structure is coupled to a receiver end of the embedded dielectric waveguide.

4. The package structure of claim 3, wherein the transmitter coupling structure comprises a pair of transmitter electrodes coupled to the transmission end portion of the embedded dielectric waveguide, and the receiver coupling structure comprises a pair of receiver electrodes coupled to the receiver end of the embedded dielectric waveguide.

5. The package structure of claim 4,
wherein the pair of transmitter electrodes comprise a first transmitter electrode and a second transmitter electrode, the first transmitter electrode and the second transmitter electrode are disposed at opposite surfaces of the transmission end portion of the embedded dielectric waveguide, and
wherein the pair of receiver electrodes comprise a first receiver electrode and a second receiver electrode, the first receiver electrode and the second receiver electrode are disposed at opposite surfaces of the receiver end of the embedded dielectric waveguide.

6. The package structure of claim 5, wherein the semiconductor die comprises a transmitter circuit and a receiver circuit, the transmitter circuit is electrically connected to the first transmitter electrode, the second transmitter electrode is electrically grounded, the receiver circuit is electrically connected to the first receiver electrode, and the second receiver electrode is electrically grounded.

7. The package structure of claim 1 further comprising:
first conductive terminals disposed between the interposer and the semiconductor die, wherein the interposer is electrically connected to the semiconductor die through the first conductive terminals; and
second conductive terminals disposed between the interposer and the wiring substrate, wherein the interposer is electrically connected the wiring substrate through the second conductive terminals.

8. The package structure of claim 7 further comprising:
an underfill disposed between the interposer and the semiconductor die, wherein the first conductive terminals are laterally encapsulated by the underfill; and
an insulating encapsulant disposed on the interposer, wherein the insulating encapsulant laterally encapsulates the semiconductor die and the underfill.

9. The package structure of claim 1, wherein the semiconductor die comprises a transmitter circuit and a receiver circuit, the transmitter circuit is electrically connected to a transmission end portion of the embedded dielectric waveguide, and the receiver circuit is electrically connected to a receiver end of the embedded dielectric waveguide.

10. A package structure, comprising:
a photonic interposer comprising conductive wirings, a first embedded dielectric waveguide and a second embedded dielectric waveguide;
a wiring substrate electrically connected to the photonic interposer; and
a semiconductor die electrically connected to the photonic interposer, the wiring substrate and the semiconductor die being disposed at opposite side of the photonic interposer, wherein the second embedded dielectric waveguide is disposed between the first embedded dielectric waveguide and the semiconductor die, and electromagnetic signals propagated in the second embedded dielectric waveguide have higher transmission frequency than electromagnetic signals propagated in the first embedded dielectric waveguide.

11. The package structure of claim 10, wherein the photonic interposer comprises:
a semiconductor substrate comprising through vias; and
dielectric layers stacked on the semiconductor substrate, wherein the conductive wirings, the first embedded dielectric waveguide and the second embedded dielectric waveguide are embedded in the dielectric layers.

12. The package structure of claim 10 further comprising an insulating encapsulant laterally encapsulating the semiconductor die, wherein sidewalls of the insulating encapsulant are substantially aligned with sidewalls of the photonic interposer.

13. The package structure of claim 10, wherein the semiconductor die comprises a transmitter circuit and a receiver circuit, and the conductive wirings comprise:
a first transmitter electrode electrically connected to the transmitter circuit;
a second transmitter electrode electrically grounded;
a first receiver electrode electrically connected to the receiver circuit; and
a second receiver electrode electrically grounded.

14. The package structure of claim 13, wherein
the first transmitter electrode and the second transmitter electrode are disposed at opposite surfaces of the transmission end portion of the embedded dielectric waveguide,
the first receiver electrode and the second receiver electrode are disposed at opposite surfaces of the receiver end of the embedded dielectric waveguide.

15. A package structure, comprising:
a photonic interposer comprising conductive wirings and embedded dielectric waveguides coupled to portions of the conductive wirings;
a wiring substrate electrically connected to the photonic interposer; and
a semiconductor die electrically connected to the photonic interposer, the wiring substrate and the semiconductor die being disposed at opposite side of the photonic interposer, wherein the embedded dielectric waveguides are different in transmission frequency.

16. The package structure of claim 15, wherein the photonic interposer comprises:
a semiconductor substrate comprising through vias; and
dielectric layers stacked on the semiconductor substrate, wherein the conductive wirings and the embedded dielectric waveguides are embedded in the dielectric layers.

17. The package structure of claim 15 further comprising an insulating encapsulant laterally encapsulating the semiconductor die, wherein sidewalls of the insulating encapsulant are substantially aligned with sidewalls of the photonic interposer.

18. The package structure of claim 15, wherein the semiconductor die comprises a transmitter circuit and a receiver circuit, and the portions of the conductive wirings comprise:
a first transmitter electrode electrically connected to the transmitter circuit;
a second transmitter electrode electrically grounded;
a first receiver electrode electrically connected to the receiver circuit; and
a second receiver electrode electrically grounded.

19. The package structure of claim 18, wherein
the first transmitter electrode and the second transmitter electrode are disposed at opposite surfaces of the embedded dielectric waveguide,
the first receiver electrode and the second receiver electrode are disposed at opposite surfaces of the embedded dielectric waveguide.

20. The package structure of claim 18, wherein
the first transmitter electrode and the first receiver electrode are disposed on a first surface of the embedded dielectric waveguide,
the second transmitter electrode and the second receiver electrode are disposed on a second surface of the embedded dielectric waveguide.
